(19) United States
(12) Patent Application Publication
(10) Pub. No.: US 2023/0084432 A1
(43) Pub. Date: Mar. 16, 2023

(54) NICKEL-BORON COATINGS FOR HOUSINGS AND ENCLOSURES

(71) Applicant: Western Digital Technologies, Inc., San Jose, CA (US)

(72) Inventors: Muralidharan SUNDARARAJAN, Penang (MY); Mutharasu DEVARAJAN, Penang (MY)

(21) Appl. No.: 17/476,227

(22) Filed: Sep. 15, 2021

(51) Int. Cl. C23C 18/34; H05K 5/04; H05K 5/00; H05K 5/02

(52) U.S. Cl. CPC C23C 18/34; H05K 5/04; H05K 5/0091; H05K 5/0217

(57) ABSTRACT

Embodiments of the present disclosure generally relate to housings and enclosures for electronic devices and memory devices, and more specifically to such housings and enclosures having nickel-boron coatings and processes for forming such nickel-boron coatings. In an embodiment is provided an article for housing at least a portion of an electronic device that includes a metal-containing substrate, and a layer comprising nickel and boron, the layer disposed on at least a portion of the metal-containing substrate, wherein: an amount of nickel in the layer is about 95 wt % or more and an amount of boron in the layer is about 5 wt % or less based on the total amount of nickel and boron in the layer. The article has a thermal conductivity of about 25 W/mK or more, a scratch hardness of about 0.5 GPa or more, a coefficient of friction of about 0.4 or less, or combinations thereof.

### BACKGROUND OF THE DISCLOSURE

### Field of the Disclosure

Embodiments of the present disclosure generally relate to housings and enclosures for electronic devices and memory devices, and more specifically to such housings and enclosures having nickel-boron coatings and processes for forming such nickel-boron coatings.

### Description of the Related Art

Polymers and resins such as epoxy, paint, and acrylic are commonly used for coating metal housings and enclosures of solid state drive (SSD) products, hard disk drive (HDD) products, heat-sink products, and retail packaging (RPG) products such as USB connectors. However, the soft nature, viscoelastic behavior, and low thermal conductivity of such polymer-based materials affects its practical value. For example, when a drive has a conventional polymer-coated enclosure, a typical contact between thermal interface materials and the enclosure coating fails to dissipate the drive's heat effectively. The soft nature of the conventional coatings also renders the coatings and enclosures prone to scratching and abrasion. In addition, the rejection of SSD, HDD, and RPG packaging and enclosures due to the presence of oil bleed on the enclosure surface, together with the low scratch and abrasion resistance of the enclosures, can be upwards of 10% in some instances.

Currently, there are very limited approaches to solving such issues for products unrelated to the electronics industry, let alone for SSD, HDD, RPG, other memory devices, and electronic devices. For example, to mitigate scratching or improve corrosion resistance, nickel-boron (NiB) coatings have been utilized for saws, piston rings and bearings, or other structures subjected to cutting action and friction forces, but are not used as scratch-resistant coatings for enclosure and packaging applications where surface properties can be key in determining whether a product is rejected. Moreover, such NiB coatings typically contain an additional material such as a stabilizer or a metal like thallium or gold, rendering such coatings unusable, atom-inefficient, and/or amorphous. Further, conventional NiB coating techniques typically involve the use of an alkaline deposition bath with a borohydride reducing agent and require a heat treatment process to attain corrosion resistance and hardness. Such alkaline baths and borohydride reagents are incompatible with typical housing and enclosure substrates of electronic devices and memory devices, while the heat treatment process is an extra operation that decreases throughput and drives up manufacturing costs.

There is a need for new and improved nickel-boron coatings for housings and enclosures of, e.g., electronic devices and memory devices that overcome one or more deficiencies in the art.

### SUMMARY OF THE DISCLOSURE

Embodiments of the present disclosure generally relate to housings and enclosures for electronic devices and memory devices, and more specifically to such housings and enclosures having nickel-boron coatings and processes for forming such nickel-boron coatings.

In an embodiment, an article for housing at least a portion of an electronic device is provided. The article includes a metal-containing substrate, and a layer comprising nickel and boron, the layer disposed on at least a portion of the metal-containing substrate, wherein: an amount of nickel in the layer is about 95 wt % or more based on a total amount of nickel and boron in the layer, the total amount of nickel and boron in the layer not to exceed 100 wt %; and an amount of boron in the layer is about 5 wt % or less based on the total amount of nickel and boron in the layer. The article has a thermal conductivity (ISO 22007-2) of about 25 W/mK or more, a scratch hardness (ISO 4586-2) of about 0.5 GPa or more, a coefficient of friction (ASTM G133) of about 0.4 or less, or combinations thereof.

In another embodiment, an article is provided. The article includes an electronic device, and a coated substrate disposed on at least a portion of the electronic device, the coated substrate including a metal-containing substrate, and a coating layer disposed over at least a portion of the metal-containing substrate, the coating layer having a thickness of about 15 μm or less, the coating layer comprising an amount of nickel of about 95 wt % or more based on a total amount of nickel and boron of the coating layer, and an amount of boron of about 5 wt % or less based on the total amount of nickel and boron in the coating layer, the total amount of nickel and boron in the coating layer not to exceed 100 wt %. The coated substrate has a thermal conductivity (ISO 22007-2) of about 25 W/mK or more, a scratch hardness (ISO 4586-2) of about 0.5 GPa or more, a coefficient of friction (ASTM G133) of about 0.4 or less, or combinations thereof.

In another embodiment, a process of making a housing or enclosure for an electronic device is provided. The process includes forming, by electroless deposition in a deposition bath, a layer comprising nickel and boron on a substrate, wherein the deposition bath is formed from a nickel source, a boron source, and a complexing agent, an amount of nickel in the layer is about 95 wt % or more based on a total amount of nickel and boron in the layer, and an amount of boron in the layer is about 5 wt % or less based on the total amount of nickel and boron in the layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a cross-section of an example article according to at least one embodiment of the present disclosure.

FIG. 1B is a cross-section of an example article according to at least one embodiment of the present disclosure.

FIG. 2 is an exploded view of an example article according to at least one embodiment of the present disclosure.

FIG. 3 is a top perspective exploded view of an example hard disk drive cover and a disk drive assembly incorporating an article described herein according to at least one embodiment of the present disclosure.

FIG. 4 is a perspective of a top side view of an example USB flash drive incorporating an article described herein according to at least one embodiment of the present disclosure.

FIG. 5 illustrates selected operations of an example process for forming an article according to at least one embodiment of the present disclosure.

FIG. 6 is an exemplary scanning electron microscope (SEM) image of an example electroless NiB (ENB) coated enclosure according to at least one embodiment of the present disclosure (scale: 1 μm).

FIG. 7A is an exemplary temperature profile at 25° C. of an example ENB coated enclosure and a comparative enclosure according to at least one embodiment of the present disclosure.

FIG. 7B is an exemplary temperature profile at 40° C. of an example ENB coated enclosure and a comparative enclosure according to at least one embodiment of the present disclosure.

FIG. 8 shows exemplary data for abrasion resistance of an example ENB coated enclosure and a comparative enclosure according to at least one embodiment of the present disclosure.

FIG. 9A is an exemplary image showing oil contamination of a comparative coated enclosure.

FIG. 9B is an exemplary image showing no oil contamination for an example ENB coated enclosure according to at least one embodiment of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to housings and enclosures for electronic devices and memory devices, and more specifically to such housings and enclosures having nickel-boron coatings and processes for forming such nickel-boron coatings. The inventors have found a nickel-boron (NiB) coated enclosure/housing having, e.g., improved thermal characteristics, increased contact area for improved heat dissipation, scratch resistance, and wear resistance, and improved durability in the presence of grease and oil relative to conventional enclosures. In some examples, articles such as enclosures and housings for such as solid state drive (SSD), hard disk drive (HDD), heat-sink products, and retail packaging (RPG) products are provided that include a NiB coating on at least a portion of a surface of the substrate enclosure or housing. The NiB coating can be a NiB alloy or material having about 95% or more Ni and 5% or less B. In some embodiments, the NiB alloy or material can be deposited on a substrate surface via an electroless deposition technique that includes the use of an acidic bath in the presence of a suitable reducing agent.

In use, the NiB coating described herein can, e.g., dissipate heat from semiconductor junctions, thereby enhancing device life span and efficiency. Other properties of the new and improved coated enclosures, housings, and packaging described herein, e.g., scratch resistance, friction, and water-repellency, are improved over conventional coated enclosures, housings, and packaging of memory devices and electronic devices. Moreover, the electroless deposition described herein improves the thermal, surface, and tribo-mechanical properties of the NiB-coated articles and NiB coated substrates relative to conventional coatings.

Conventional techniques for depositing nickel-boron materials are not suitable for enclosures or housings of electronic devices and memory devices. For example, conventional techniques typically involve the use of alkaline baths with a borohydride reducing agent. Under such alkaline conditions (pH of 10-14), metal substrates such as aluminum containing substrates are unstable and begin to dissolve. In addition, conventional NiB-containing coatings will have other materials to stabilize the coating such as thallium or gold, and the formed NiB coatings are amorphous. In contrast, the NiB coating formed by processes described herein can show crystalline nickel peaks.

Moreover, conventional NiB deposition techniques also focus on heat treatment processes to attain desired hardness properties, corrosion resistance, and other characteristics. In contrast, embodiments described herein are free of such heat treatment processes.

Embodiments of the present disclosure generally relate to housings and enclosures for electronic devices and memory devices. Such articles described herein show improved thermal, mechanical, and surface properties relative to state-of-the-art enclosures and housings.

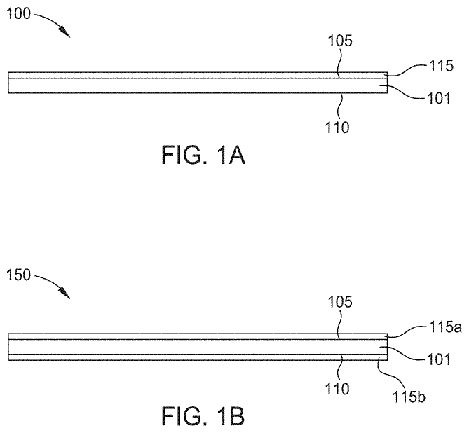

FIG. 1A is a cross section of an example article 100 according to at least one embodiment. The article 100 can be, e.g., structure utilized to, e.g., enclose, cover, surround, and/or house at least a portion of a memory device, electronic device, a component utilized with a memory device, a component utilized with an electronic device, and/or various other devices/products. Article 100 can be an enclosure, a case, a housing, panel, a base, a cover, or any other suitable structure to, e.g., enclose, cover, surround, and/or house at least a portion of a device or product. Generally, the article 100 includes at least two components.

The article 100 includes a first component 101 (or substrate), which may be made of or include a metal or metal alloy such as aluminum (Al), stainless steel, iron, zinc, chromium, magnesium, brass, cobalt, copper, alloys thereof, or combinations thereof. The first component 101 has a first surface 105 and a second surface 110. The second surface 110 can be the surface on a memory device, an electronic device, heat-sink device, or a component utilized with a memory device, an electronic device, a heat-sink device, or other device/product. The first component 101 can be of any suitable shape or size in order to, e.g., enclose, cover, surround, and/or house at least a portion of a memory device, electronic device, heat-sink device, a component utilized with a memory device, a component utilized with an electronic device, a component utilized with heat-sink device, and/or various other devices/products. A thickness of the first component 101 can be from about 100 microns (μm) to about 25,000 μm, such as from about 250 μm to about 5000 μm, such as from about 1000 μm to about 2500 μm, such as from about 2500 μm to about 10,000 μm, such as from about 5000 μm to about 20,000 μm. A larger or smaller thickness for the first component 101 is contemplated.

The article 100 also includes a second component 115 (or coating layer) disposed on at least a portion of the first surface 105 of the first component 101. As shown in FIG. 1A, only a single second component 115 is disposed on a surface of the substrate. It is also contemplated that a plurality of second components are disposed on surfaces of the first component. Here, for example, and as shown in article 150 of FIG. 1B, second component 115a is disposed on at least a portion of the first surface 105 of the first component 101, and second component 115b is disposed on at least a portion of the second surface 110 of the first component 101. Reference herein to the second component 115 shall include reference to the second components 115a, 115b, individually, unless the context indicates otherwise.

The second component 115 is a coating utilized for, e.g., increasing contact area with a component for improved heat dissipation and for improved scratch- and wear-resistance relative to conventional material coatings. The second component 115 can be a composition that includes nickel (Ni) and boron (B), such as a NiB alloy, a material containing Ni and B, a reaction product comprising Ni and B, or combinations thereof. In some embodiments, and as described below, the second component 115 (e.g., the NiB alloy or material containing Ni and B) can be deposited on one or more surfaces of the first component 101 via an electroless deposition technique that includes the use of an acidic bath in the presence of a suitable reducing agent. Each of the first component 101 and the second component 115, individually, can be in the form a layer or a plurality of layers. In some embodiments, articles 100 and 150 are coated substrates that include a substrate (e.g., first component 101) and one or more layers comprising nickel and boron (e.g., the second component 115). For example, and in some embodiments, the coated substrate includes a metal enclosure for housing an electronic device (corresponding to the first component 101) and also includes a coating layer (corresponding to the second component 115) disposed over at least a portion of the metal enclosure.

A weight percent of Ni in the second component 115 can be about 90 wt % or more, such as from about 91 wt % to about 99 wt %, such as from about 92 wt % to about 98 wt %, such as from about 93 wt % to about 97 wt %, such as from about such as from about 94 wt % to about 96 wt %, based on a total amount of Ni and B in the second component 115 (not to exceed 100 wt %). In at least one embodiment, the weight percent of Ni in the second component 115 is about 95 wt % to about 99 wt %, such as from about 95 wt % to about 97 wt % or from about 96 wt % to about 98 wt %, based on the total amount of Ni and B in the second component 115. The weight percent of Ni in the second component 115 is determined according to ASTM E1508-12a on the surface of the specified material using energy dispersive x-ray spectrometry (EDX).

A weight percent of B in the second component 115 can be about 10% or less, such as from about 1 wt % to about 9 wt %, such as from about 2 wt % to about 8 wt %, such as from about 3 wt % to about 7 wt %, such as from about such as from about 4 wt % to about 6 wt %, based on the total amount of Ni and B in the second component 115. In at least one embodiment, the weight percent of B in the second component 115 is about 1 wt % to about 5 wt %, such as from about 3 wt % to about 5 wt % or from about 2 wt % to about 4 wt %, based on the total amount of Ni and B in the second component 115. The weight percent of B in the second component 115 is determined according to ASTM E1508-12a using EDX spectrometry.

A thickness of the second component 115 (or coating layer) can be about 20 μm or less, such as about 15 μm or less, such as from about 1 μm to about 10 μm, such as from about 2 μm to about 9 μm, such as from about 3 μm to about 8 μm, such as from about 4 μm to about 7 μm, such as from about 5 μm to about 6 μm. A larger or smaller thickness for the second component 115 is contemplated.

In some embodiments, a third component (not shown), such as a metal-containing layer can be disposed between at least a portion of the first component 101 and a portion of the second component 115. The third component can be in the form of a layer that includes zinc or a zinc-containing material. A thickness of this third component, if present, can be about 3 μm or less, such as about 2 μm or less, such as from about 0.05 μm to about 2 μm, such as from about 0.5 μm to about 1 μm, such as about 1 μm to about 3 μm. A larger or smaller thickness for this third component is contemplated.

The articles and coated substrates described herein such as article 100 or article 150, which includes the first component 101 and the second component 115 (e.g., NiB coating layer) disposed thereon have improved properties over conventional enclosures, cases, and covers as discussed below. The articles or coated substrates described herein (e.g., article 100 and article 150) can have one or more of the following properties:

The article or coated substrate can have an average surface roughness that is about 0.1 μm or more such as about 0.2 μm or more and/or about 3 μm or less, such as from about 0.1 μm to about 3 μm, such as from about 0.2 μm to about 2 μm, such as from about 0.3 μm to about 1 μm. In at least one embodiment, the average surface roughness of the article or coated substrate can be about 0.2 μm or more, such as about 0.2 μm to about 0.4 μm. A higher or lower average surface roughness of the article or coated substrate is contemplated. Average surface roughness is a measure of surface profile or finely spaced micro-irregularities on the surface of the specified material at different locations and is commonly used to indicate the level of roughness. Average surface roughness is determined according to ISO 4287:1997 using Mitutoyo surface profilometry.

The article or coated substrate can have a scratch width that is about 100 or more, such as about 125 μm or more, such as about 150 μm or more, such as about 175 μm or more, such as about 185 μm or more. In at least one embodiment, the article or coated substrate has a scratch width that is from about 20 μm to about 100 μm, such as from about 25 μm to about 95 μm, such as from about 30 μm to about 90 μm, such as from about 35 μm to about 85 μm, such as from about 40 μm to about 80 μm, such as from about 45 μm to about 75 μm, such as from about 50 μm to about 70 μm, such as from about 55 μm to about 65 μm. In some embodiments, the article or coated substrate has a scratch width that is from about 65 μm to about 75 μm. A higher or lower scratch width of the article or coated substrate is contemplated. Scratch width is a measure of groove width dimension under constant applied load and is used to indicate scratch resistance, with lower values indicating higher scratch resistance of the specified material. Scratch width is determined using a Taber scratch tester according to ISO 4586-2.

The article or coated substrate can have a scratch hardness of about 0.5 gigapascals (GPa) or less and/or about 0.4 GPa or less, such as about 0.3 GPa or less and/or about 0.2 GPa or less, such as from about 0.05 GPa to about 0.5 GPa, such as from about 0.1 GPa to about 0.4 GPa, such as from about 0.15 GPa to about 0.35 GPa, such as from about 0.2 GPa to about 0.35 GPa, such as from about 0.3 GPa to about 0.35 GPa, such as from about 0.2 GPa to about 0.3 GPa, such as from about 0.25 GPa to about 0.3 GPa. In at least one embodiment, the scratch hardness of the article or coated substrate is about 0.5 GPa or more, such as about 0.55 GPa or more, such as from about 1 GPa to about 4 GPa, such as from about 1.5 GPa to about 3.5 GPa, such as from about 1.75 GPa to about 3 GPa, such as from about 1.75 GPa to about 2.75 GPa or from about 2 GPa to about 2.5 GPa. A higher or lower scratch hardness of the article or coated substrate is contemplated. Scratch hardness is a measure of scratch resistance, with higher values indicating higher scratch resistance of the specified material. Scratch hardness is determined using a Taber scratch tester according to ISO 4586-2.

The article or coated substrate can have a coefficient of friction (unitless) that is about 0.5 or less, such as about 0.4 or less, such as about 0.35 or less, such as about 0.3 or less, such as about 0.25 or less, such as about 0.2 or less, such as about 0.15 or less, such as about 0.1 or less. In at least one embodiment, the coefficient of friction of the article or coated substrate is from about 0.01 to about 0.3, such as from about 0.05 to about 0.25, or from about 0.05 to about 0.1, or from about 0.1 to about 0.2. A higher or lower coefficient of friction of the article or coated substrate is contemplated. The coefficient of friction of the article is a measure of abrasion resistance, with lower values indicating higher abrasion resistance of the specified material. Coefficient of friction is determined using a pin-on-disc abrasion tester according to ASTM G133.

The article or coated substrate can have a thermal conductivity of about 10 watts per meter-kelvin (W/(mK)) or more, such as about 25 W/mK or more and/or about 75 W/mK or less, such as from about 30 W/mK to about 60 W/mK, such as from about 35 W/mK to about 50 W/m K, such as from 35 W/mK to about 40 W/mK or from about 40 W/mK to about 45 W/mK. In at least one embodiment, the thermal conductivity of the article or coated substrate is about 30 W/mK to about 40 W/mK or from about 30 W/mK to about 50 W/mK. A higher or lower thermal conductivity of the article or coated substrate is contemplated. Thermal conductivity measures the degree to which a specified material conducts heat. Thermal conductivity is determined using a Hotdisk TPS 2500S thermal constant analyzer according to ISO 22007-2.

The article or coated substrate can have a contact angle of about 100° or more, such as from about 100° to about 150°, such as from about 105° to about 145°, such as from about 110° to about 140°, such as from about 115° to about 135°, such as from about 120° to about 130°. In at least one embodiment, the contact angle of the article or coated substrate is from about 100° to about 135°, such as from about 105° to about 130°, such as from about 110° to about 125°, such as from to about 115° to about 120°. In some embodiments, the contact angle of the article or coated substrate is about 110° or more such as from about 110° to about 135°. The contact angle is a quantitative measure of wetting by a material or its hydrophobicity. Contact angle is determined using a Rame-hart Goniometer according to ASTM D7334-08.

In at least one embodiment, the article or coated substrate has: a thermal conductivity of about 30 W/mK to about 40 W/mK; a scratch width of about 65 μm to about 75 μm; a scratch hardness of about 1.5 GPa to about 2.5 GPa; a coefficient of friction of about 0.05 to about 0.1; a contact angle of about 100° to about 130°; and/or a surface roughness of about 0.2 μm to about 0.4 μm.

As described above, the articles or coated substrates described herein, e.g., article 100 and article 150, can be a structure utilized to, e.g., enclose, cover, surround, and/or house at least a portion of a memory device, electronic device, a component utilized with a memory device, a component utilized with an electronic device, and/or various other devices/products. Such articles or coated substrates can be an enclosure, a case, a housing, panel, a base, a cover, or any other suitable structure to, e.g., enclose, cover, surround, and/or house at least a portion of a device or product.

Illustrative, but non-limiting, examples of electronic devices, memory devices, and other devices that can be utilized with articles or coated substrates described herein include hard disk drive (HDD), solid state drive (SSD), universal serial bus (USB) flash drive, laptop housing, keyboard, mouse, SSD packaging, HDD packaging, sensor cover, camera cover, wi-fi router, automotive music system, CPU cover, plastic casing for electrical electronic goods, and components thereof. Also included are retail packaging (RPG) products such as USB connectors, and components thereof, as well as heat-sink products such as heat exchangers, heat pipes, microchannel, pin fins, and components thereof.

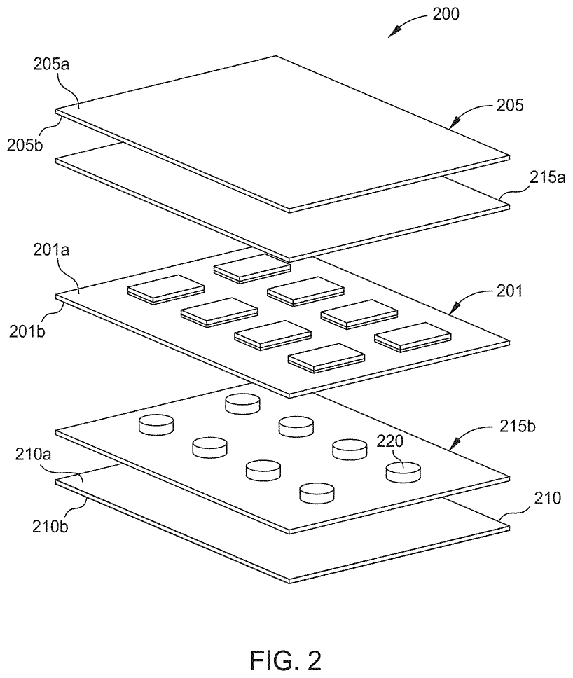

FIG. 2 is an exploded view of an example electronic package in the form of a solid state drive cover and assembly 200 according to at least one embodiment. The cover and assembly includes a printed circuit board (PCB) layer 201 with optional components mounted thereon. The PCB layer 201 has a top surface 201a and a bottom surface 201b. A first cover 205 (or enclosure) is disposed on at least a portion of the top surface 201a of the PCB layer 201. A second cover 210 (or enclosure) is disposed on at least a portion of the bottom surface 201b of the PCB layer 201.

A first coating layer 215a containing Ni and B can be disposed between the top surface 201a of the PCB layer 201 and a bottom surface 205b of the first cover 205. The first coating layer 215a can be disposed over at least a portion of the top surface 201a of the PCB layer 201 and/or disposed over at least a portion of the bottom surface 205b of the first cover 205. A second coating layer 215b containing Ni and B can be disposed between the bottom surface 201b of the PCB layer 201 and a top surface 210a of the second cover 210. The second coating layer 215b can be disposed over at least a portion of the bottom surface 201b of the PCB layer 201 and/or disposed over at least a portion of the top surface 210a of the second cover 210. In some examples, liquid thermal interface materials (shown as the round-shaped discs 220) can be utilized with articles described herein.

In some embodiments, a coating layer (not shown) containing Ni and B can be disposed on at least a portion of the top surface 205a of the first cover 205, disposed on at least a portion of the bottom surface 210b of the second cover 210, or both. The various coating layer+enclosure/cover shown in FIG. 2 can correspond to article 100 or article 150. For example, first coating layer 215a disposed over at least a portion of the bottom surface 205b of the first cover 205 corresponds to article 100 or article 150.

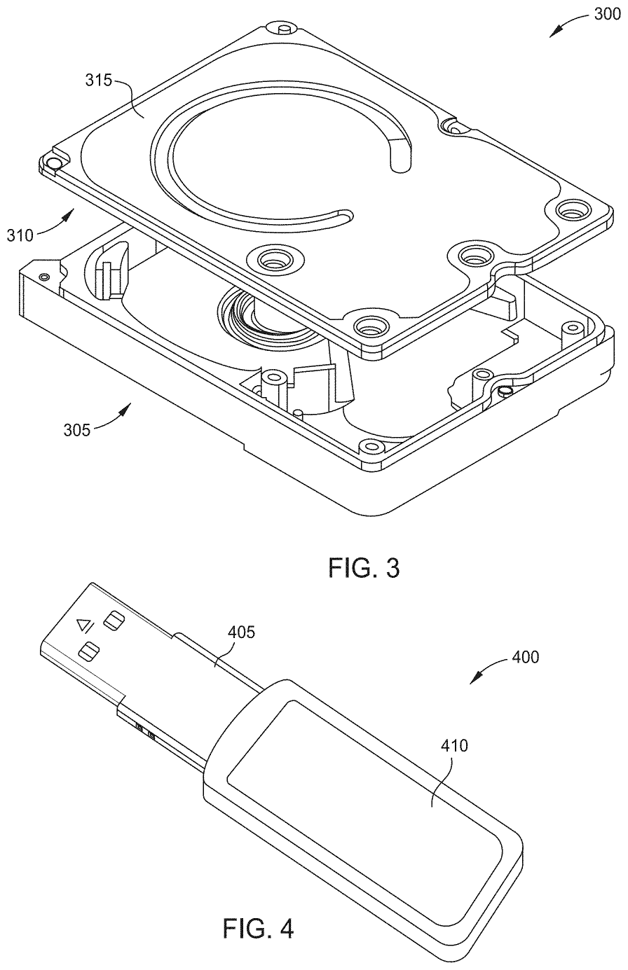

FIG. 3 is a top perspective exploded view of an example hard disk drive cover and a disk drive assembly 300 according to at least one embodiment. The hard disk drive cover and assembly includes a cover 310 having an outer surface 315 and a base assembly. At least a portion of the base assembly 305, cover 310, and/or outer surface 315 can include article 100 or 150 described above. Other portions such as the inner surface(s) of the hard disk drive cover and a disk drive assembly 300 can include article 100 or article 150 described above.

FIG. 4 is a perspective of a top side of an example USB flash drive 400 incorporating an article described herein according to at least one embodiment. The USB flash drive 400 includes a cover 410 enclosing, covering, surrounding, and/or housing at least a portion of a USB device 405. At least a portion of cover 410 can include article 100 or article 150 described above. Other portions such as the inner surface(s) of the USB flash drive 400 can include article 100 or article 150 described above.

The electronic and memory devices shown in FIGS. 2-4 are non-limiting illustrations of uses for articles and coated substrates described herein and are not intended to limit the scope of embodiments of the present disclosure.

Embodiments of the present disclosure also relate to processes for making an article or coated substrate, e.g., article 100 or article 150. Generally, and in some embodiments, at least a portion of the substrate (or first component 101) can be contacted with various mixtures or compositions, sequentially, to form a layer comprising nickel and boron (or second component 115) on the substrate. Processes described herein enable, e.g., a uniform or substantially uniform coating thickness of an NiB-containing layer on the substrate, having various shapes or morphologies, and enable bulk manufacturing of articles.

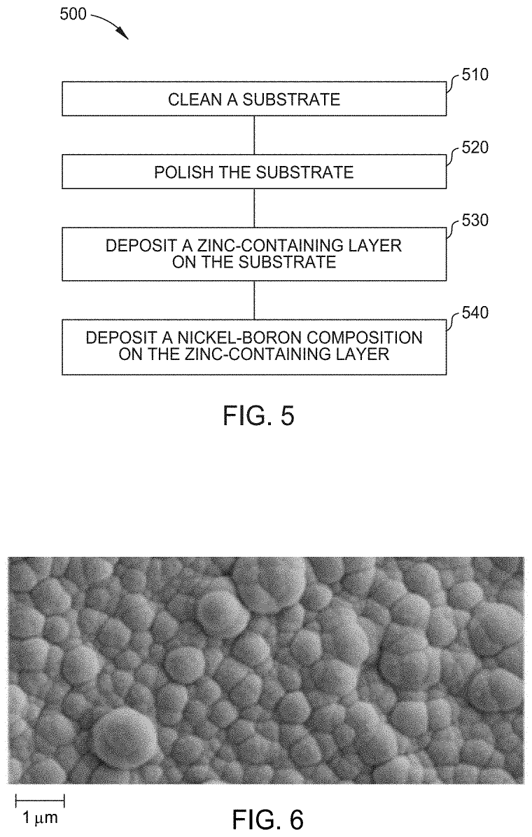

FIG. 5 shows selected operations of an example process 500 for forming an article according to at least one embodiment. The process begins with cleaning of a substrate (or the first component 101) to remove the presence of, e.g., oils, greases, waxes, metallic fines, dirt particles, and/or other contaminants present on the substrate at operation 510. The substrate can be made of or include a suitable metal and/or metal alloy utilized for enclosures and housings, such as Al, stainless steel, iron, zinc, chromium, magnesium, brass, cobalt, copper alloys thereof, or combinations thereof. The cleaning process of operation 510 includes introducing the substrate with an alkaline bath under cleaning conditions. The cleaning conditions of operation 510 can include a temperature ranging from about 10° C. to about 50° C., from about 20° C. to about 40° C.; from about 25° C. to about 35° C.; a pressure ranging from about 400 Torr to about 1200 Torr, such as from about 600 Torr to about 1000 Torr; from about 700 to 800 Torr; and/or a duration of time of about 30 minutes to about 10 h, such as from about 1 h to about 5 h, such as from about 2 h to about 3 h. Here, the substrate can be dipped in or otherwise immersed in the alkaline bath. Additionally, or alternatively, the alkaline bath can be sprayed on the substrate. The alkaline bath typically has a pH of about 8 to about 12, such as from about 9 to about 11, and can be an aqueous solution that includes detergent(s), soap oil cleaner(s), or combinations thereof. The alkaline bath can include suitable materials such as soap oil, detergent, and combinations thereof. A ratio of the soap oil to detergent can be from about 5:1 to about 1:5, such as from about 3:1 to about 1:3, such as from about 2:1 to about 1:2, such as about 1:1.

Once the substrate is cleaned to a desired specification, the substrate can be optionally washed with, sprayed with, or immersed in, water to remove residual alkaline bath. The water wash can be performed for a period of about 30 minutes or less, such as from about 5 minutes to about 10 minutes. Additionally, or alternatively, and after the cleaning process of operation 510 (with optional water washing), the substrate can be degreased utilizing one or more organic solvents. Suitable organic solvents for degreasing the substrate include, but are not limited to, ketone solvents such as acetone and/or methyl ethyl ketone, alcohol solvents such as ethanol and/or isopropanol. Combinations of organic solvents can be used. For example, a ˜1:1 mixture of acetone to ethanol can be utilized to degrease the substrate. Such a degreasing operation, if desired, can be performed for a time duration of about 1 h or less, such as about 30 min or less, such as about 20 min or less.

The process 500 further includes polishing the substrate at operation 520. The polishing process of operation 520 can include introducing the substrate with a polishing solution/mixture under polishing conditions to form a polished substrate. The polishing solution/mixture can include suitable materials to polish the metal(s) and/or metal alloy(s) of the substrate. The polishing solution can be an aqueous solution containing one or more acids inorganic acids such as HNO₃, H₂SO₄, H₂CrO₄, HCl, H₃PO₄, or combinations thereof in suitable proportions. A non-limiting example of a polishing solution or mixture includes HNO₃, H₂SO₄, and water at varying proportions such as from about 40 vol % to about 60 vol % HNO₃, 20 vol % to about 30 vol % H₂SO₄, and the remainder of the solution being water. The polishing solution or mixture can have a pH of about 2 to about 6, such as from about 3 to about 5. The polishing conditions of operation 520 can include a temperature ranging from about 10° C. to about 50° C., such as from about 20° C. to about 40° C., such as from about 25° C. to about 35° C.; a pressure ranging from about 400 Torr to about 1200 Torr, from about 600 Torr to about 1000 Torr, from about 700 to 800 Torr; and/or a duration of time of about 1 min to about 20 min, such as from about 3 min to about 15 min, such as from about 3 min to about 5 min or from about 5 min to about 10 min. Here, the substrate can be dipped in or otherwise immersed in the polishing solution/mixture. Additionally, or alternatively, the polishing solution/mixture can be sprayed on the substrate.

In some embodiments, the polishing solution or mixture can additionally, or alternatively, include various water soluble mineral acid salts, such as alkali metal and ammonium sulfates and bisulfates. Illustrative, but non-limiting, examples include sodium sulfate, sodium bisulfate, potassium sulfate, potassium bisulfate, ammonium sulfate and ammonium bisulfate. Mixtures of such salts can be utilized. The polishing solution can additionally, or alternatively, include a salt of an organic acid. Such organic acid salts can help control oxidation and decomposition of various species in the polishing solution. Illustrative, but non-limiting, examples of organic acid salts can include alkali metal or ammonium salts of acetic acid, citric acid, tartaric acid, gluconic acid, lactic acid, propionic acid, or mixtures thereof. Non-limiting examples include sodium tartrate, sodium gluconate, potassium citrate, potassium gluconate, potassium lactate, etc.

The process 500 further includes depositing a zinc-containing layer on the substrate at operation 530. Such a process is referred to as “zincating,” and generally includes immersing the substrate in an acid zinc bath or alkaline zinc bath to deposit a thin zinc-containing layer. The resultant zinc-containing layer (or zincate layer) can minimize oxidation of the substrate surface. A typical process sequence for depositing a zinc-containing layer generally includes zincating, chemical stripping of zincate layer, and zincating the surface again. This two-operation zincating process can be performed before the electroless NiB deposition, discussed below, to, e.g., facilitate plating of the NiB on the substrate.

The first zincating process of operation 530 includes introducing the polished substrate with a zincating bath at a temperature ranging from about 10° C. to about 50° C., such as from about 20° C. to about 40° C.; such as from about 25° C. to about 35° C.; a pressure ranging from about 400 Torr to about 1200 Torr, from about 600 Torr to about 1000 Torr, from about 700 Torr to about 800 Tor; and/or a duration of time of about 10 sec to about 100 sec, such as from about 20 sec to about 80 sec, such as from about 30 sec to about 60 sec, such as from about 40 sec to about 50 sec. Here, the substrate can be dipped in or otherwise immersed in the zincating bath. The zincating bath includes an aqueous solution of a zinc source (such as zinc hydroxide and/or zinc oxide) and an alkali metal hydroxide such as sodium hydroxide. The zincating bath can also include ferric chloride and a tartrate/tartrate ion source (such as a salt of tartaric acid, such as potassium sodium tartrate, also known as rochelle salt). In some embodiments, the zincating bath can have various amounts of these materials, such as the following formulation ranges: ˜250-325 g/L of NaOH, ˜5-12 g/L of zinc oxide, ˜0.75-1.5 g/L ferric chloride, and ˜0.1-1 g/L potassium sodium tartrate. Another zincating solution that can be used with embodiments of the present disclosure include, e.g., U.S. application Ser. No. 10/265,864, which is incorporated herein by reference in its entirety.

The zincating layer formed from the first zincating process of operation 530 can be stripped or otherwise removed from the substrate by immersing the substrate in an acid zinc bath contains HNO₃ and water. In some embodiments, the acid bath can have amounts of these materials, such as the following formulation ranges: 20-80 g/L of HNO₃ (nitric acid) and the remainder water. For example, the acid bath can include 50% nitric acid and 50% water. The zinc layer can be removed from the substrate with an acid bath at a temperature ranging from about 10° C. to about 50° C., such as from about 20° C. to about 40° C.; such as from about 25° C. to about 35° C.; a pressure ranging from about 400 Torr to about 1200 Torr, from about 600 Torr to about 1000 Torr, from about 700 Torr to about 800 Torr; and/or a duration of time of about 10 sec to about 100 sec, such as from about 20 sec to about 80 sec, such as from about 30 sec to about 60 sec, such as from about 40 sec to about 50 sec. The second zincating process of operation 530 can be performed in the same or similar manner as the first zincating process discussed above.

The zinc-containing layer formed from operation 530 can have a thickness of about 0.05 μm to about 3 μm, such as from about 0.1 μm to about 2 μm, though a larger or smaller thickness of the zinc-containing layer is contemplated.

Process 500 further includes depositing a composition comprising nickel and boron on the zinc-containing material at operation 540. This composition comprising Ni and B can be a NiB alloy, a material containing Ni and B, a reaction product comprising Ni and B, the like, or combinations thereof. The composition comprising Ni and B can be in the form of a layer such as an NiB coating layer, e.g., second component 115. Operation 540 is an electroless NiB deposition process which generally refers to an autocatalytic process where the substrate can develop a potential in a deposition bath (or plating bath) containing nickel ions and other components.

Operation 540 includes introducing the substrate having the Zn-containing layer formed thereon with a deposition bath under deposition conditions. The deposition conditions of operation 540 can include a temperature greater than about 50° C. and/or about 100° C. or less, such as from about 55° C. to about 80° C., such as from about 60° C. to about 75° C., such as from about 65° C. to about 70° C.; a pressure ranging from about 400 Torr to about 1200 Torr, such as from about 600 Torr to about 1000 Torr, such as from about 700 Torr to about 800 Torr; and/or a duration of time of about 30 min or more, such as from about 1 h to about 3 h, such as from about 1.5 h to about 2.5 h. Generally, the substrate is dipped in, or otherwise immersed in, the deposition bath.

The deposition bath of operation 540 can include a Ni source, a boron source, a complexing agent, and a stabilizer in suitable proportions. The deposition bath of operation 540 can be an aqueous solution/suspension having an acidic pH, such as from about 4 to about 6, such as from about 4.5 to about 5.5, such as from about 4.5 to about 5 or from about 5 to about 5.5. In at least one embodiment, the deposition bath for operation 540 has a pH from about 4 to about 5.5, such as from about 4 to about 4.5, 4.5 to about 5, or from about 5 to about 5.5.

The nickel source, which can be a plurality of nickel sources, used for the deposition bath of operation 540 can include any suitable source of Ni such as nickel sulfate, nickel acetate, nickel chloride, or combinations thereof. An amount of nickel source(s) used for the deposition bath can be from about 25 wt % to about 50 wt %, such as from about 26 wt % to about 38.5 wt %, such as from about 30 wt % to about 36.5 wt %, such as from about 32 wt % to about 34.5 wt % based on a total weight of nickel source, boron source, complexing agent, and stabilizer of the deposition bath. In some embodiments, an amount of nickel source can be from about 25-40 g/L, such as from about 30-35 g/L.

The boron source, which can also act as a reducing agent, used for the deposition bath of operation 540 can include amines such as alkyl amines, such as dimethylamine borane ((CH₃)₂NHBH₃), diethylamine borane, trimethylamine borane, triethylamine borane, or combinations thereof. More than one boron source can be utilized. An amount of boron source(s) used for the deposition bath can be from about 1.9 wt % to about 3.1 wt %, such as from about 2 wt % to about 3 wt %, such as from about 2.1 wt % to about 2.9 wt % based on the total weight of nickel source, boron source, complexing agent, and stabilizer of the deposition bath. In some embodiments, an amount of boron source can be from about 2-3 g/L, such as from about 2-2.5 g/L or about 2.5-3 g/L.

One or more complexing agents can be included in the deposition bath of operation 540. The complexing agent utilized for the deposition bath of operation 540 can include a salt of an organic acid. Illustrative, but non-limiting, examples of organic acid salts can include alkali metal or ammonium salts of acetic acid, citric acid, tartaric acid, gluconic acid, lactic acid, propionic acid, or combinations thereof. Non-limiting examples include sodium citrate, sodium acetate, sodium tartrate, sodium gluconate, potassium citrate, potassium acetate, potassium gluconate, potassium lactate, and combinations thereof. An amount of complexing agent(s) in the deposition bath (e.g., when one or more complexing agents are used for the deposition bath) can be from about 27 wt % to about 39 wt %, such as from about 29 wt % to about 37 wt %, such as from about 31 wt % to about 36 wt %, such as from about 33 wt % to about 34.5 wt % based on the total weight of nickel source, boron source, complexing agent, and stabilizer of the deposition bath.

In some embodiments and when two complexing agents are utilized in the deposition bath of operation 540, an amount of a first complexing agent used in the deposition bath can be about 10-30 g/L, such as about 15-25 g/L; and/or an amount of second complexing agent used in the deposition can be about 8-30 g/L, such as about 10-30 g/L, such as about 15-25 g/L.

One or more stabilizers such as an alcohol (such as methanol, ethanol, and/or propanol), lead, ammonia or combinations thereof, can be included in the deposition bath of operation 540. An amount of stabilizer(s) in the deposition bath can be from about 28 wt % to about 33 wt %, such as from about 28.5 wt % to about 32 wt %, such as from about 29 wt % to about 31 wt % based on the total weight of nickel source, boron source, complexing agent, and stabilizer of the deposition bath. In some embodiments, an amount of stabilizer used in the deposition bath can be about 20-50 mL/L, such as about 25-45 mL/L, such as about 30-40 mL/L.

A weight ratio of nickel source(s) to boron source(s) in the deposition bath of operation 540 can be from about 1:10 to about 1:15, such as from about 1:11 to about 1:14, such as from about 1:12 to about 1:13. In at least one embodiment, the weight ratio of nickel source(s) to boron source(s) in the deposition bath of operation 540 is from about 1:11.7 to about 1:13.3, such as from about 1:12.5 to about 1:13, such as from about 1:11 to about 1:12.5.

A weight ratio of nickel source(s) to complexing agent(s) in the deposition bath of operation 540 can be from about 9:10 to about 19:20, such as from about 9:11.7 to about 13.5:20, such as from about 9:12.5 to about 11.7:13.5, such as from about 11.7:11.75 to about 13.5:20.

A weight ratio of nickel source(s) to stabilizer(s) in the deposition bath of operation 540 can be from about 9:12 to about 18:13, such as from about 9.5:11 to about 13:17, such as from about 10:13 to about 11:13. In at least one embodiment, the weight ratio of nickel source(s) to stabilizer(s) in the deposition bath of operation 540 is from about 9.8:11.7 to about 16.6:13.3, such as from about 9.8:10.5 to about 12.5:16.6, such as from about 10:12.5 to about 10.5:13.3.

A weight ratio of boron source(s) to complexing agent(s) in the deposition bath of operation 540 can be from about 1:12 to about 1:14, such as from about 1:11.7 to about 1:13.3, such as from about 1:12.5 to about 1:13, such as from about 1:11 to about 1:12.5

A weight ratio of boron source(s) to stabilizers(s) in the deposition bath of operation 540 can be from about 1:10 to about 1:17, such as from about 1:9.8 to about 1:16.6, such as from about 1:10 to about 1:15, such as from about 1:9.8 to about 1:12.

A weight ratio of stabilizers(s) to complexing agent(s) in the deposition bath of operation 540 can be from about 9:10 to about 20:13.3, such as from about 9.8:11.7 to about 13.3:15, such as from about 10:12 to about 10:13.3.

The weight percent of nickel source(s), boron source(s), complexing agent(s), and stabilizer(s) in the deposition bath of operation 540 is determined based the starting material weight percent used for making the deposition bath. The weight ratios of the components in the deposition bath of operation 540 are determined based the starting material weight ratio used for making the deposition bath.

The deposition bath of operation 540 is formed in an aqueous solution or suspension such that the nickel source, boron source, complexing agent(s), and/or other components can be in the form of ions, e.g., Ni ion, organic acid ion, and so forth. In the solution/suspension, the dimethylamine borane (DMAB) complex can decompose to boric acid, borates, hydrogen, and dimethylamine. Such components can also be in the deposition bath. Reaction product(s) of the components of the deposition bath may also be in the deposition bath.

The electroless NiB deposition of operation 540 enables uniform or substantially uniform coating of a layer comprising NiB on a substrate having a layer thickness as described above. This NiB coating can have a nano-nodular type structure or morphology. Illustrative characteristics of the NiB coated structures (e.g., article 100 and article 150) formed by operations of process 500 are described above.

The following examples are put forth so as to provide those of ordinary skill in the art with a complete disclosure and description of how to make and use aspects of the present disclosure, and are not intended to limit the scope of embodiments of the present disclosure. Efforts have been made to ensure accuracy with respect to numbers used (e.g. amounts, dimensions, etc.) but some experimental errors and deviations should be accounted for.

### Examples

The weight percent of each of Ni and B is determined according to ASTM E1508-12a on the surface of the specified material using energy dispersive x-ray spectrometry (Quanta 650 FEG, SEM) on a 10 mm×10 mm sample. Average surface roughness is determined according to ISO 4287:1997 using Mitutoyo surface profilometry as described below. Scratch width is determined using a Taber scratch tester according to ISO 4586-2 as described below. Scratch hardness is determined using a Taber scratch tester according to ISO 4586-2 as described below. Coefficient of friction is determined using a pin-on-disc abrasion tester according to ASTM G133 as described below. Thermal conductivity is determined using a Hotdisk TPS 2500S thermal constant analyzer according to ISO 22007-2 as described below. Contact angle is determined using a Rame-hart Goniometer according to ASTM D7334-08.

### 1. Example NiB Coated Enclosure.

A NiB coated enclosure was formed according to the following general procedure. An aluminum alloy substrate (die cast ADC-12 aluminum alloy) was subjected to alkaline cleaning using detergent and soap oil cleaner at 1:1 ratio for two hours and then gently washed with distilled water for 5-10 minutes. The substrate was then degreased using a 1:1 mixture of acetone and ethanol for 20 minutes. The cleaned substrate was then polished by immersing the substrate in a polishing bath (40-60% nitric acid, 20-30% sulfuric acid, with the remainder being distilled water).

The polished substrate was then processed through zincate steps. The zincating bath included NaOH (˜250-325 g/L), zinc oxide (˜5-12 g/L), ferric chloride (˜0.7-1.5 g/L), and potassium sodium tartrate (˜0.1-1 g/L) in distilled water is about 700-980 ml range. The zincating bath was run at a temperature of about 25° C., a pressure of about 760 Torr, for about 40 sec. The Zn layer was removed by immersing the substrate into bath consists of 50% HNO₃ and 50% distilled water combination at a temperature of about 25° C., a pressure of about 760 Torr, for a duration of about 30 sec. The substrate was then re-immersed in the same zincating bath under similar conditions to form the Zn layer on the substrate.

The substrate having a zinc layer deposited thereon was then subjected to an electroless NiB deposition. Various example formulations for the electroless deposition bath and conditions for the deposition are shown in Table 1. During the deposition, control factors such as pH and bath temperature were continuously monitored and maintained.

TABLE 1

| | Example | Example |
|---|---|---|
| | Formulation Range | Formulation |
| Nickel sulfate, g/L | ~25-40 | ~30 |
| Dimethylamine borane, g/L | ~2-3 | ~2.55 |
| Sodium acetate, g/L | ~10-30 | ~20 |
| Sodium citrate, g/L | ~8-30 | ~10 |
| Methanol, mL/L | ~20-50 | ~25 |
| Conditions | Condition Range | Example Condition |
| pH | ~4-5.5 | ~4.5 |
| Bath temperature, ° C. | ~55-80 | ~70 |
| Deposition time, min | ~90-150 | ~120 |

The deposition yielded a Ni—B coating with a substantially uniform distribution of nano-nodular structured morphology, ˜95-97 wt % of Ni and ˜3-5 wt % of B elements together with ˜6-7 μm thickness on an Al enclosure substrate. FIG. 6 is an exemplary SEM image is captured using Quanta 650 FEG scanning electron microscopy of an example electroless NiB (ENB) coated enclosure. The image shows the nano-nodular character of the ENB coating. When mounted to a thermal interface material (TIM), this nano-nodular coating can, e.g., increase contact points between the TIM and the enclosure, leading to improve heat dissipation.

Various properties of the example electroless NiB (ENB) coated enclosures were evaluated against comparative coated enclosures. These properties, discussed further below, include heat dissipation, scratch resistance, abrasion resistance, oil contamination, thermal conductivity, contact angle, and surface roughness parameters. The comparative coated enclosure utilized for the evaluations are an epoxy coated aluminum alloy substrate.

### 2. Example Heat Dissipation

To investigate heat dissipation properties, functional thermal mapping using VDBench software was performed on an example ENB coated enclosure and a comparative coated enclosure (epoxy coated aluminum alloy substrate). The thermal mapping measures the thermal behavior of the coated enclosures under a controlled-force air flow. The experimental setup involves attaching thermocouples to the location of the hottest spots (referred to as T1, T2, T3, and T4 hot spots) on the coated enclosures, performing a thermal scan, and recording the temperature readings. Example test conditions for the heat dissipation evaluations are shown in Table 2.

TABLE 2

| | |
|---|---|
| Ambient conditions | ~25° C. and ~40° C. |
| Test condition of drive | 100% sequential write function |
| Temperature scan | T-type thermocouple |
| Air velocity control | 2.3 m/s using wind tunnel chamber |
| Test duration | 2 hours with 10 second indexing |

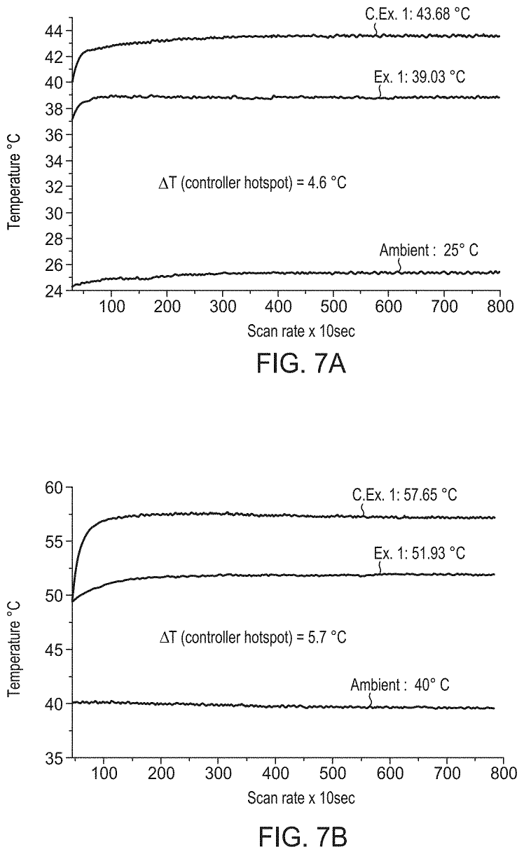

FIGS. 7A and 7B show exemplary temperature profiles of an example ENB coated enclosure (Ex. 1) and a comparative coated enclosure (C. Ex. 1) at ˜25° C. and ˜40° C., respectively, measured at thermocouple controller location T1. The data illustrated in FIGS. 7A and 7B indicate that the example ENB coated enclosure effectively dissipates heat. Moreover, the data demonstrates the significant improvement in heat dissipation of the example ENB coated enclosure relative to the comparative coated enclosure, showing an improvement of ˜4.6° C. and ˜5.7° C. at the T1 hot spot on the enclosure.

Table 3 shows exemplary data for the temperature reduction (AT) of the example ENB coated enclosure relative to the comparative coated enclosure through each thermocouple at different hot spots on the enclosures. T1, T2, T3, and T4 refer to the location of the thermocouples at the hottest spots. NAND spot refers to the locations of thermocouples at T2 & T4 spots. Controller spot refers to the location of thermocouple at T1 spot and secondary or back side of controller refers to the location of T3 spot.

For example, and using FIG. 2, top surface 201a of the PCB layer 201 has NAND (T2) and controller (T1) components. The respective hot spots are fixed with thermocouples on the top surface 205a of the first cover 205. The bottom surface 201b of the PCB layer 201 has NAND components only. The corresponding thermocouple T4 is located on the bottom surface 210b of the second cover 210. Although there is no controller placed on the bottom surface 201b of the PCB layer 201, the controller hot spot located at the top surface 201a of the PCB layer 201 influences the bottom surface 210b of the second cover 210, and thus T3 is located at the bottom surface 210b of the second cover 210.

TABLE 3

| | Ambient | C. Ex. 1 | Ex. 1 | ΔT |
|---|---|---|---|---|
| Thermocouple | (° C.) | (° C.) | (° C.) | (° C.) |
| T1 (Controller spot-top) | 40 | 57.6 | 51.9 | 5.7 |
| T2 (NAND spot) | 40 | 52.0 | 47.9 | 4.1 |
| T3 (Controller spot-bottom) | 40 | 53.2 | 49.8 | 3.4 |
| T4 (NAND spot) | 40 | 52.8 | 49.6 | 3.2 |
| T1 (Controller spot-top) | 25 | 43.6 | 39.0 | 4.6 |
| T2 (NAND spot) | 25 | 38.0 | 34.2 | 3.8 |
| T3 (Controller spot-bottom) | 25 | 39.3 | 36.4 | 2.7 |
| T4 (NAND spot) | 25 | 38.6 | 36.2 | 2.4 |

Overall, the data in Table 3 indicates that the example ENB coating has a significant impact on reducing the component's junction and enclosure temperature. For example, ΔT ranges from about 2.4° C. to about 5.7° C., indicating the significant improvement in heat dissipation of the example ENB coated enclosure over the comparative coated enclosure. The ˜10-12% improved heat dissipation of the ENB coated enclosure over the comparative coated enclosure shows that the ENB coated enclosure can improve the life span of various components within the enclosure and/or around the enclosure.

### 3. Example Tribological and Other Properties

Conventional enclosures are rejected at high rates for various reasons including poor scratch resistance, poor abrasion resistance, and oil contamination, among others. Such yield loss issues result in high manufacturing costs and waste. Embodiments described herein solve these and other issues.

Scratch resistance properties such as scratch width and scratch hardness were investigated on example ENB coated enclosures and comparative coated enclosures. The comparative coated enclosures investigated were an epoxy coated aluminum substrate. The scratch resistance properties of the coated enclosures were determined according to ISO 4586-2 using scratch tester Taber 550/551. Here, a substantially flat 70 mm×70 mm NiB coated sample is mounted on the scratch test table to make the scratch under an applied load.

The coated enclosures were ploughed with a diamond tool (0.5 kg applied load, constant velocity) and then viewed under a microscope. The comparative coated enclosures showed poor scratch resistance under the 0.5 kg applied load which is likely due to the epoxy polymer's viscoelastic nature. Under the same testing conditions, the example ENB coated enclosures showed significant improvements in scratch resistance properties—scratch width and scratch hardness. For example, the comparative coated enclosures presented a scratch width of 180-190 μm and a scratch hardness of 0.2-0.5 GPa while the example ENB coated enclosures displayed a scratch width of about 65 μm to about 75 μm and a scratch hardness of about 1.5 GPa to about 2.5 GPa. The test indicated that scratch width was substantially improved by about 60-70% using the example ENB coated enclosures relative to the comparative coated enclosures. Further, the scratch hardness was significantly improved. Here the scratch hardness of the example ENB coated enclosures was up to about 12 times greater, or more, than the comparative coated enclosures. Overall, the results indicate that the example ENB coated enclosures have very high scratch resistance properties relative to conventional enclosures. This data also shows that the ENB coatings can eliminate, or at least reduce, the rejection of drives (yield loss) due to scratch-resistance performance.

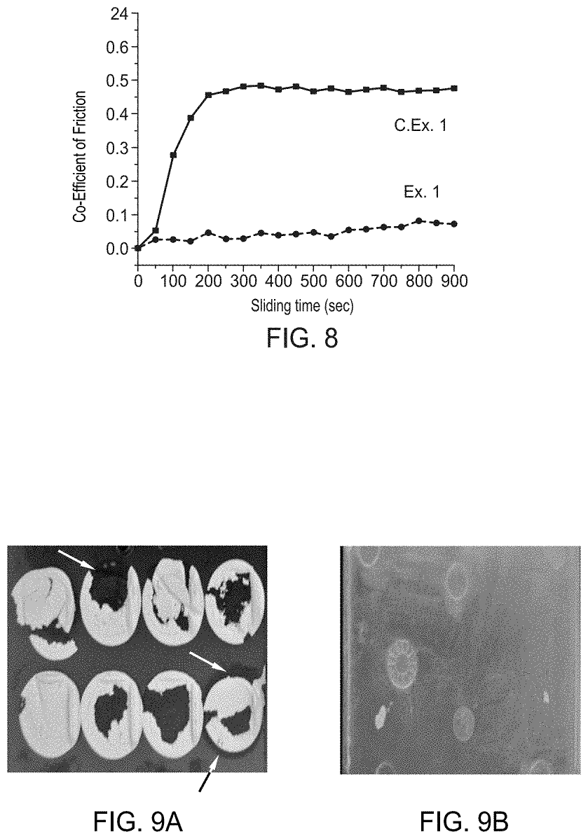

Abrasion resistance was also evaluated in order to investigate, e.g., long-lasting performance and surface durability of the example ENB coated enclosures relative to comparative coated enclosures. Abrasion resistance is measured by determining a coating's frictional force against a normal load (coefficient of friction, CoF). Typically, it is desired for the coating's CoF to be as low as possible. The coefficient of friction of the example ENB coated enclosures and comparative coated enclosures were determined according to ASTM G133 and measured using a DUCOM POD 4.0. Here, a flat sample (70 mm×20 mm) of a substrate coated with NiB is mounted on the table. The CoF experiments involve placing the samples to be investigated under a repeated, reciprocating motion of a EN52100 ball (10 mm diameter). The ball is rubbed with 0.5 kg applied load against the coating's surface with a sliding distance of 10 mm at 1 Hz frequency. FIG. 8 shows exemplary data for the CoF of an example ENB coated enclosure (Ex. 1) and a comparative coated enclosure (C. Ex. 1).

As shown in FIG. 8, the comparative coated enclosure had an increased friction coefficient up to about 0.5. Visually, the coating layer of the comparative coated enclosure deformed easily, leading to very high friction on its surface. Under the same testing conditions, the example ENB coated enclosure displayed a significantly lower coefficient of friction of about 0.05, and a negligible wear rate or visual deformity after 900 seconds of sliding time. That is, the ENB coating resulted in a five-times better CoF over the conventional coated enclosure without any defects or deformations. Without wishing to be bound by theory, it is believed that the improved coefficient of friction of the example ENB coated enclosures relative to the comparative coated enclosures is due to, e.g., the lubricity behavior of boron and the uniform coating layer of the example ENB coated enclosures.

Such superior abrasion resistance and CoF performance is enabled through the ENB coated articles and ENB processes described herein. Overall, the results indicate that the example ENB coated enclosures described herein have very high abrasion resistance relative to conventional enclosures. The ENB coatings can eliminate, or at least reduce, the rejection of drives due to abrasion yield loss.

Oil contamination is another issue that arises during manufacturing, leading to the rejection of memory drives and other devices. Oil contamination can be due to curing conditions where conventional enclosures have a tendency to expose silicon oil seepage on its surface.

For example, liquid thermal interface materials (LTIM)—shown as the round-shaped discs in FIG. 2—can be dispensed on an enclosure surface. The LTIM can be made of an elastomeric type of material that contains a silicone medium. The LTIM serves to transport the heat from hot spot component to the ambient through contacting the enclosures. Once the LTIM is dispensed on the enclosure, the PCB with the entire drive assembled can be cured in the oven for about 30 min at 100° C. After curing, epoxy-coated enclosures exhibit visible oil contamination. In contrast, the ENB coated enclosure of the present disclosure do not exhibit visible oil contamination or marks.

FIG. 9A is an image of a comparative enclosure showing visible oil contamination/seepage (indicated by the arrows). Typically, such oil bleeding requires cleaning the enclosure or housing with isopropanol to remove the oil contamination marks. In contrast, and as shown by the image of FIG. 9B, the example ENB coated enclosure displayed no visible oil contamination or seepage. As such, the ENB coating can facilitate higher throughput via, e.g., eliminating the isopropanol cleaning step and lower yield loss.

Table 4 shows a summary of properties of example ENB coated enclosures described herein against comparative coated enclosures (epoxy coated enclosures). Thermal conductivity was determined according to ISO 22007-2 and measured using a Hot disc TPS 2500s thermal conductivity analyzer. To measure the thermal conductivity, a kapton insulated TPS sensor is placed between two identical NiB coated (70 mm×70 mm) samples. Contact angle was determined according to ASTM D7334-08 and measured using a Rame-hart goniometer. A flat 70×70 mm Ni—B coated substrate is mounted on the bench table and a controlled amount of 5 μl water is dispensed on the Ni—B surface using a nozzle. Using drop image in build software the contact angle between solid surface-liquid medium is measured and discussed. Surface roughness was determined according to ISO 4287:1997 and measured using a Mitutoyo SJ410 surface roughness profilometery using a 60°/2 μm stylus indenter under 0.75 mN measuring force. A 70 mm×70 mm NiB coated substrate is placed on granite table followed by the indenter is traced on the surface for 4.0 mm stroke length to obtain the average roughness value.

TABLE 4

| | Comparative | Example ENB |
|---|---|---|
| Property | Coated Examples | Coated Enclosures |
| Thermal conductivity, W/mK | 10-25 | ~30-40 |
| Scratch width, μm | 180-190 | ~65-75 |
| Scratch hardness, GPa | 0.2-0.5 | ~1.5-2.5 |
| Coefficient of friction, unitless | 0.4-0.5 | ~0.05-0.1 |
| Contact angle, degrees (°) | 95-105 | ~100-135 |
| | (hydrophobic) | (hydrophobic) |
| Surface roughness, μm | 0.1-0.3 | ~0.2-0.4 |
| Oil-bleed contamination | Yes | No |

The data in Table 4 indicates the thermal, mechanical, and surface performance of the ENB coated enclosures described herein. For example, the thermal conductivity of the example ENB coated enclosures relative to the comparative coated enclosure is improved by more than about 20-30%. The surface roughness of ENB coated surface can remain almost similar as epoxy coated surface, but can slightly improve as shown in Table 4.

The hydrophobicity, or water-repellency, of the coating can enable a self-cleaning behavior of the coating surface against various liquid mediums. Here, the hydrophobicity improved to about 135° as measured by contact angle. As such, coating contamination issues can be reduced relative to conventional coatings and the surface appearance of the example coatings can remain more intact.

Embodiments described herein generally relate to housings, enclosures, and packaging for, e.g., memory devices or electronic devices, and to processes for forming such housings, enclosures, and packaging. Overall, the electroless NiB coatings described herein have better thermal performance, scratch & wear resistance, surface finish, and hydrophobic properties relative to conventional coatings used for enclosures. Moreover, surfaces of the example electroless NiB coated enclosures showed no oil bleed. The data further indicates that the coatings described herein can be useful for enclosures or housings of various electronic devices, memory devices, heat-sink products, and other devices and products such as SSD, HDD and RPG metal enclosures.

As used herein, a “composition” can include component(s) of the composition and/or reaction product(s) of two or more components of the composition.

In the foregoing, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the aforementioned embodiments, aspects, features, and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

For purposes of this present disclosure, and unless otherwise specified, all numerical values within the detailed description and the claims herein are modified by “about” or “approximately” the indicated value, and consider experimental error and variations that would be expected by a person having ordinary skill in the art. For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

As used herein, the indefinite article “a” or “an” shall mean “at least one” unless specified to the contrary or the context clearly indicates otherwise.

While the foregoing is directed to embodiments of the present disclosure, other and further embodiments of the disclosure may be devised without departing from the basic scope thereof, and the scope thereof is determined by the claims that follow.

1. An article for housing at least a portion of an electronic device, the article comprising:
a metal-containing substrate; and
a layer comprising nickel and boron, the layer disposed on at least a portion of the metal-containing substrate, wherein:
an amount of nickel in the layer is about 95 wt % or more based on a total amount of nickel and boron in the layer, the total amount of nickel and boron in the layer not to exceed 100 wt %; and
an amount of boron in the layer is about 5 wt % or less based on the total amount of nickel and boron in the layer,
the article having:
a thermal conductivity (ISO 22007-2) of about 25 W/mK or more;
a scratch hardness (ISO 4586-2) of about 0.5 GPa or more;
a coefficient of friction (ASTM G133) of about 0.4 or less; or
combinations thereof.

2. The article of claim 1, wherein the article has:
a scratch width (ISO 4586-2) of about 180 μm or less;
a contact angle (ASTM D7334-08) of about 100° or more;
a surface roughness (ISO 4287:1997) of about 0.1 μm or more; or
combinations thereof.

3. The article of claim 1, further comprising a zinc-containing layer disposed between at least a portion of the metal-containing substrate and the layer comprising nickel and boron.

4. The article of claim 1, wherein the article has:
a thermal conductivity (ISO 22007-2) of about 30 W/mK to about 50 W/mK;
a scratch hardness (ISO 4586-2) of about 1 GPa to about 3 GPa;
a coefficient of friction of about 0.3 or less; or
combinations thereof.

5. The article of claim 4, wherein the article has:
a scratch width (ISO 4586-2) of about 100 μm or less;
a contact angle (ASTM D7334-08) of about 110° or more;
a surface roughness (ISO 4287:1997) of about 0.2 μm or more; or
combinations thereof.

6. The article of claim 1, wherein the electronic device comprises a hard disk drive, a solid state drive, a universal serial bus (USB) flash drive, USB packaging, SSD packaging, HDD packaging, or components thereof.

7. The article of claim 1, wherein the metal-containing substrate comprises aluminum, stainless steel, iron, zinc, chromium, magnesium, brass, cobalt, copper alloys thereof, or combinations thereof.

8. The article of claim 1, wherein the amount of nickel in the layer is from about 95 wt % to about 97 wt %, and the amount of boron in the layer is from about 3 wt % to about 5 wt %.

9. An article, comprising:
an electronic device;
a coated substrate disposed on at least a portion of the electronic device, the coated substrate comprising:
a metal-containing substrate; and
a coating layer disposed over at least a portion of the metal-containing substrate, the coating layer having a thickness of about 15 μm or less, the coating layer comprising:
an amount of nickel of about 95 wt % or more based on a total amount of nickel and boron of the coating layer; and
an amount of boron of about 5 wt % or less based on the total amount of nickel and boron in the coating layer, the total amount of nickel and boron in the coating layer not to exceed 100 wt %,
the coated substrate having:
a thermal conductivity (ISO 22007-2) of about 25 W/mK or more;
a scratch hardness (ISO 4586-2) of about 0.5 GPa or more;
a coefficient of friction (ASTM G133) of about 0.4 or less; or
combinations thereof.

10. The article of claim 9, wherein:
the thermal conductivity of the coated substrate is about 30 W/mK to about 50 W/m K;
the scratch hardness of the coated substrate is about 1 GPa to about 3 GPa;
the coefficient of friction of the coated substrate is about 0.3 or less; or
combinations thereof.

11. The article of claim 9, wherein the coated substrate has:
a scratch width (ISO 4586-2) of about 100 μm or less;
a contact angle (ASTM D7334-08) of about 110° or more;
a surface roughness (ISO 4287:1997) of about 0.2 μm or more; or
combinations thereof.

12. The article of claim 9, wherein the coated substrate has at least three of the following properties:
a thermal conductivity (ISO 22007-2) of about 30 W/mK to about 40 W/mK;
a scratch width (ISO 4586-2) of about 65 μm or to about 75 μm;
a scratch hardness (ISO 4586-2) of about 1.5 GPa to about 2.5 GPa;
a coefficient of friction of about 0.1 or less;
a contact angle (ASTM D7334-08) of about 110° to about 135°; or
a surface roughness (ISO 4287:1997) of about 0.2 μm to about 0.4 μm.

13. The article of claim 9, wherein the electronic device comprises a hard disk drive, a solid state drive, a universal serial bus (USB) flash drive, USB packaging, SSD packaging, HDD packaging, or components thereof.

14. A process of making a housing or enclosure for an electronic device, comprising:
forming, by electroless deposition in a deposition bath, a layer comprising nickel and boron on a substrate,
wherein:
the deposition bath is formed from a nickel source, a boron source, and a complexing agent,
an amount of nickel in the layer is about 95 wt % or more based on a total amount of nickel and boron in the layer, and
an amount of boron in the layer is about 5 wt % or less based on the total amount of nickel and boron in the layer.

15. The process of claim 14, wherein:
the nickel source comprises nickel sulfate, nickel chloride, nickel acetate, or combinations thereof; and
the boron source comprises dimethylamine borane, diethylamine borane, trimethylamine borane, triethylamine borane, or combinations thereof.

16. The process of claim 14, wherein:
the electroless deposition is performed at a temperature of about 100° C. or less; and
a pH of the deposition bath is from about 4 to about 6.

17. The process of claim 14, further comprising:
zincating the substrate prior to forming the layer comprising nickel and boron.

18. The process of claim 14, further comprising:
cleaning the substrate with an alkaline bath; and
polishing the cleaned substrate with a polishing bath comprising one or more inorganic acids, wherein cleaning and polishing is performed prior to forming the layer comprising nickel and boron.

19. The process of claim 14, wherein:
a weight ratio of the nickel source to the boron source used to form the deposition bath is from about 1:11.7 to about 1:13.3; and
a weight ratio of the nickel source to the complexing agent used to form the deposition bath is from about 9:12.5 to about 13.3:20.

20. The process of claim 14, wherein the layer comprising nickel and boron is about 15 μm or less.
